(19) United States
(12) Patent Application Publication
(10) Pub. No.: US 2016/0077133 A1
(43) Pub. Date: Mar. 17, 2016

(54) ROGOWSKI COIL AND CURRENT MEASUREMENT SENSOR INCLUDING THE SAME

(71) Applicant: SAMSUNG ELECTRO-MECHANICS CO., LTD., Suwon-si (KR)

(72) Inventors: Jae Chan LEE, Suwon-Si (KR); Kwang Myung KIM, Suwon-Si (KR); Se Jin SEO, Suwon-Si (KR); Jae Youn JEONG, Suwon-Si (KR)

(73) Assignee: SAMSUNG ELECTRO-MECHANICS CO., LTD., Suwon-si (KR)

(21) Appl. No.: 14/848,581

(22) Filed: Sep. 9, 2015

(30) Foreign Application Priority Data
Sep. 12, 2014 (KR) 10-2014-0121281

(51) Int. Cl. G01R 15/18; H01F 27/28; H01F 38/30

(52) U.S. Cl. CPC G01R 15/181; H01F 38/30; H01F 27/2823; H01F 2027/2833

(57) ABSTRACT

There is provided a current measurement sensor including: a rogowski coil having a winding coil disposed on an outer circumference part of a coaxial coil; a body case to which one end and the other end of the rogowski coil are coupled, so that the rogowski coil forms a loop; and a coupling member coupling the rogowski coil to the body case, wherein the coupling member includes: a coil coupling member having one side coupled to the rogowski coil and the other side coupled to the body case, and a case coupling member coupled to the body case and covering a coupling part between the coil coupling member and the body case.

### CROSS-REFERENCE TO RELATED APPLICATION

This application claims the benefit of Korean Patent Application No. 10-2014-0121281, filed on Sep. 12, 2014, entitled “ROGOWSKI COIL and current measurement sensor using the same” which is hereby incorporated by reference in its entirety into this application.

### BACKGROUND

The present disclosure relates to a rogowski coil and a current measurement sensor including the same.

In recent, in order to scientifically save energy and improve efficiency, a high precision current sensor having an enforced analysis function has been required for a power measurement apparatus.

In addition, as a means for achieving the above-mentioned objects, a current transformer (CT) using a magnetic coil has been used, but since there is a problem with an application, for example, it is difficult to miniaturize the current transformer (CT), a current sensor using a rogowski coil has been well used.

More specifically, the rogowski coil performs an excitation using a plastic bobbin made of a special material forming an air core without using a magnetic core unlike a general current transformer and in the case in which a current flows in a conductor penetrating through the air core, as a voltage which is proportional to the current of the conductor is induced to a coil wound around the air core by the current, the rogowski coil has a structure detecting magnitude of the current flowing in the conductor based on the induced voltage. In addition, since the rogowski coil has characteristics that does not has an over-current damage due to core saturation, it has been effectively used for apparatuses in which a high voltage current flows, such as an air circuit breaker, a gas-insulated load switch, and the like.

In addition, the current sensor using the rogowski coil according to the related art including Related Art Document forms the rogowski coil as a loop.

### RELATED ART DOCUMENT

### Patent Document

(Patent Document 1) U.S. Pat. No. 8,324,883

### SUMMARY

An aspect of the present disclosure may provide a rogowski coil capable of removing noise due to an influence of an external magnetic field, preventing damage and breakage due to external impact, and stably and accurately measuring a current, and a current measurement sensor including the same.

According to an aspect of the present disclosure, a current measurement sensor including a rogowski coil may include: a rogowski coil having a winding coil disposed on an outer circumference part of a coaxial coil; a body case to which one end and the other end of the rogowski coil are coupled, so that the rogowski coil forms a loop; and a coupling member coupling the rogowski coil to the body case, wherein the coupling member includes: a coil coupling member having one side coupled to the rogowski coil and the other side coupled to the body case, and a case coupling member coupled to the body case and covering a coupling part between the coil coupling member and the body case.

According to another aspect of the present disclosure, a rogowski coil may include: a coaxial coil; a coil tube having the coaxial coil inserted thereinto; a winding coil wound on an outer circumference surface of the coil tube at an equidistant interval; and a rogowski tube covering the winding coil.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically showing a current measurement sensor including a rogowski coil according to an exemplary embodiment of the present disclosure;

FIG. 2 is a schematic exploded perspective view of the current measurement sensor including the rogowski coil shown in FIG. 1;

FIGS. 3A, 3B, and 3C schematically shows the rogowski coil and a connection member in the current measurement sensor including the rogowski coil shown in FIG. 1, wherein FIG. 3A is a perspective view, FIG. 3B is a cross-sectional view taken along a line A-A′, and FIG. 3C is a schematic exploded perspective view of the rogowski coil and the connection member; and

FIGS. 4A, 4B, and 4C are usage state views schematically showing a process of coupling the rogowski coil to a body case in the current measurement sensor including the rogowski coil shown in FIG. 1.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

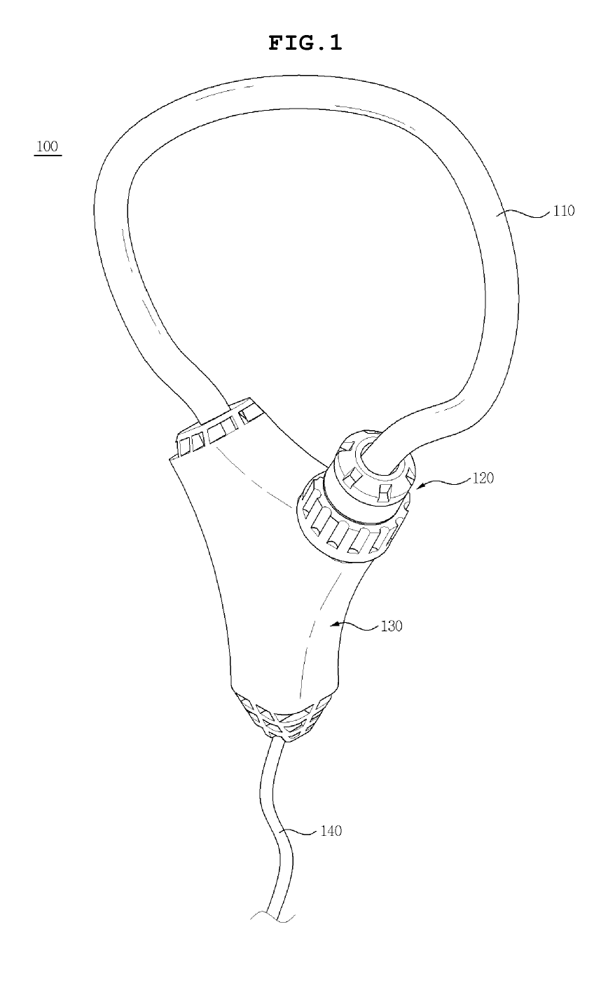

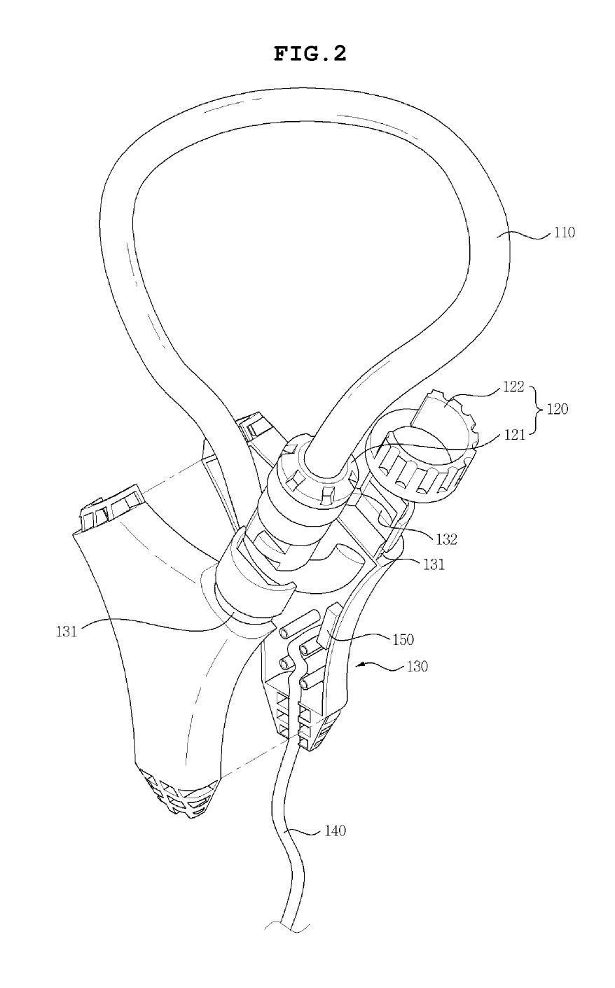

FIG. 1 is a perspective view schematically showing a current measurement sensor including a rogowski coil according to an exemplary embodiment of the present disclosure and FIG. 2 is a schematic exploded perspective view of the current measurement sensor including the rogowski coil shown in FIG. 1.

As shown, a current measurement sensor 100 including a rogowski coil includes a rogowski coil 110, a coupling member 120, a body case 130, a data cable 140, and a controlling unit 150.

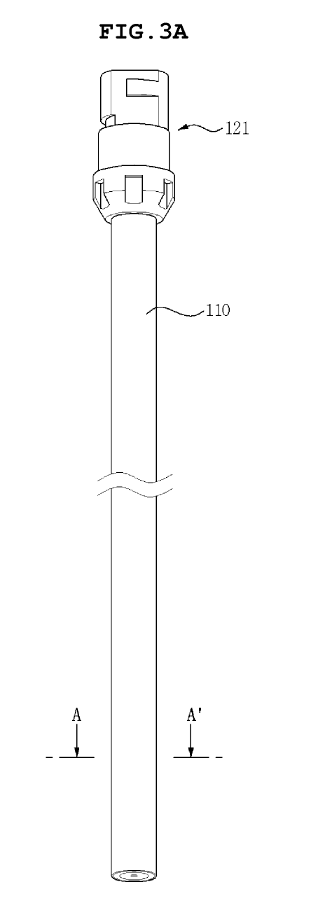

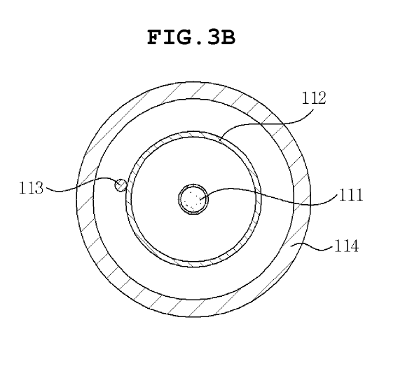

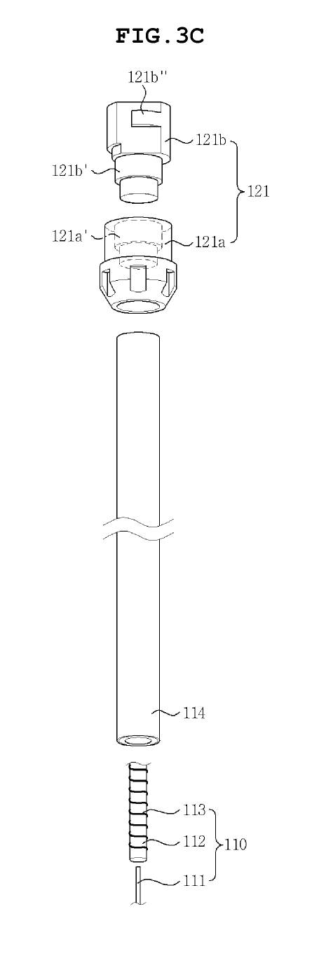

More specifically, the rogowski coil 110 is to induce an output voltage which is proportional to a current by electromagnetic induction and detailed configuration and shape for the induction of the output voltage will be described below in more detail with reference to FIGS. 3A, 3B, and 3C.

In addition, the coupling member 120 is to more effectively and stably mount one end portion of the rogowski coil 110 to the body case 130. To this end, the coupling member 120 includes a coil coupling member 121 and a case coupling member 122.

In addition, the coil coupling member 121 is coupled to one end portion of the rogowski coil 110 and the case coupling member 122 is rotatably coupled to the body case 130. In addition, in a state in which the coil coupling member 121 is coupled to the body case 130, the rogowski coil 110 is more stably mounted in the body case 130 along a cover by the case coupling member 122 and a separation of the rogowski coil 110 from the body case 130 is prevented by the coupling member 122.

In addition, the controlling unit 150 is to induce a current induced in the rogowski coil 110 as an output voltage, may be connected to the rogowski coil 110 so as to be matched and may be disposed at the shortest distance from the rogowski coil 110 in order to remove external noise.

In addition, the data cable 140 is connected to the controlling unit 150 and is to output the output voltage induced by the controlling unit 150 to an external device.

Next, the body case 130 is coupled to one end of the rogowski coil 110 and is mounted with the other end of the rogowski coil 110 by the coupling member 120 as described above so that the rogowski coil 110 forms a loop. In addition, the controlling unit 150 is mounted on the body case 130 so as to be adjacent to the rogowski coil 110. In addition, the data cable 140 is mounted in the body case 130 so that one end thereof is connected to the controlling unit 150.

In addition, an end portion side of the body case 130 is provided with a guide groove 131 to which the case coupling member 133 is rotatably and movably coupled and a coil coupling part 132 to which the coil coupling member 121 is coupled.

In addition, the body case 130 may be provided with a guide part (not shown) for fixing and guiding a mounting position of the other end portion to which the rogowski coil is coupled.

FIGS. 3A, 3B, and 3C schematically shows the rogowski coil and a connection member in the current measurement sensor including the rogowski coil shown in FIG. 1, wherein FIG. 3A is a perspective view, FIG. 3B is a cross-sectional view taken along a line A-A′ in FIG. 3A, and FIG. 3C is a schematic exploded perspective view of the rogowski coil and the connection member.

As described above, one end portion of the rogowski coil 110 is coupled to the coil coupling member 121 for mounting the rogowski coil 110 in the body case 130.

More specifically, the coil coupling member 121 includes a first coil coupling member 121a to which the rogowski coil 110 is coupled and a second coil coupling member 121b for being coupled to the body case 130.

In addition, the second coil coupling member 121b is provided with a coupling part 121b′ for being coupled to the first coil coupling member 121a and the first coil coupling member 121a is provided with a coupling part 121a′ corresponding to the coupling part 121b′.

In addition, the coupling part 121a′ of the first coil coupling member 121a and the coupling part 121b′ of the second coil coupling member 121b may be implemented by a protrusion part and a groove part corresponding to the protrusion part as shown in FIG. 3C.

In addition, the second coil coupling member 121b is provided with a case coupling part 121b″ for being coupled to the body case 130. In addition, the body case 130 is provided with a coil coupling part 132 corresponding to the case coupling part 121b″ of the second coil coupling member 121b.

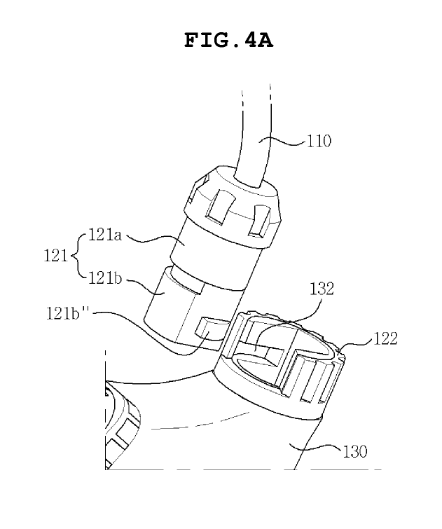

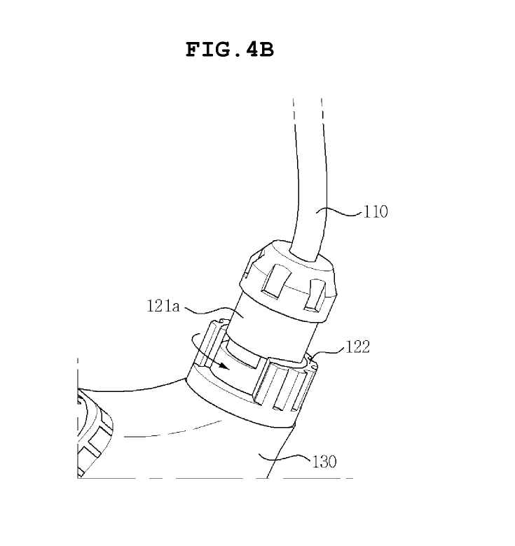

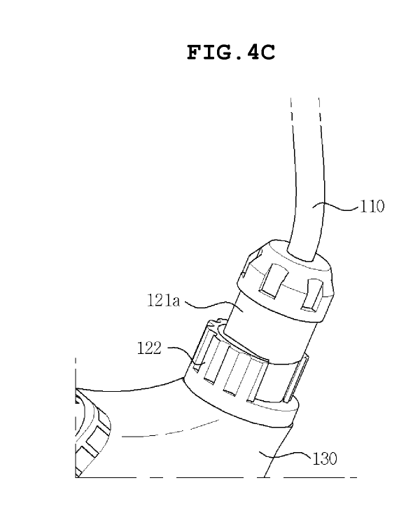

In addition, the case coupling part 121b″ of the second coil coupling member 121b and the coil coupling part 132 of the body case 130 may be implemented by a protrusion part and a groove part corresponding to the protrusion part as shown in FIG. 4A.

In addition, the coil coupling member according to an exemplary embodiment of the present disclosure may be formed so that the rogowski coil is coupled to the second coupling member and the first coupling member covers a coupling part between the second coupling member and the rogowski coil.

In addition, the first coil coupling member 121a and the second coil coupling member 121b of the coil coupling member 121 according to an exemplary embodiment of the present disclosure may be integrally formed.

Next, the rogowski coil 110 includes a coaxial coil 111, a coil tube 112, a winding coil 113, and a rogowski tube 114.

In addition, the coaxial coil 111 is inserted into the tube coil 112 and the winding coil 113 is wound on an outer circumference surface of the tube coil 112 at an equidistant interval. That is, as the winding coil 113 is wound on the outer circumference surface of the tube coil 112, it may be constantly wound according to a set turn.

In addition, the rogowski tube 114 covers the tube coil 112 in which the coaxial coil 111 is embedded and on which the winding coil 113 is wound.

By the configuration as described above, the rogowski coil 110 may be insulated so as to remove noise due to an influence of an external magnetic field and prevent damage and breakage due to external impact by the rogowski tube 114 and may stably and accurately measure the current since the winding coil 113 is flexibly wound.

FIGS. 4A, 4B, and 4C are usage state views schematically showing a process of coupling the rogowski coil to a body case in the current measurement sensor including the rogowski coil shown in FIG. 1.

First, as shown in FIG. 4A, in a state in which one end portion of the rogowski coil 110 is coupled to the coupling member 121 including the first coil coupling member 121a and the second coil coupling member 121b, the case coupling part 121b″ formed in the second coil coupling member 121b is insertedly coupled to the coupling part 132 formed in the body case 130.

Next, as shown in FIGS. 4B and 4C, the case coupling member 122 which is rotatably mounted in the body case 130 is rotated so as to cover a position at which the case coupling part 121b″ of the second coil coupling member 121b is inserted into the coupling part 132 of the body case 130, thereby blocking an external discharging direction of the second coil coupling member 121b.

That is, as the case coupling member 122 covers the other direction of the second coil coupling member 121b which is inserted into the body case 130 in one direction, the separation of the coil coupling member 121 may be prevented.

By the configuration as described above, the current measurement sensor including the rogowski coil according to the present disclosure may easily mount the rogowski coil 110 in the body case 130 and may be implemented in a more stable sensor structure by additionally performing a locking function using the case coupling member 122.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A current measurement sensor including a rogowski coil, the current measurement sensor comprising:
a rogowski coil having a winding coil disposed on an outer circumference part of a coaxial coil;
a body case to which one end and the other end of the rogowski coil are coupled, so that the rogowski coil forms a loop; and
a coupling member coupling the rogowski coil to the body case,
wherein the coupling member includes:
a coil coupling member having one side coupled to the rogowski coil and the other side coupled to the body case, and
a case coupling member coupled to the body case and covering a coupling part between the coil coupling member and the body case.

2. The current measurement sensor of claim 1, wherein the body case is provided with a guide groove and the case coupling member is rotatably coupled to the guide groove.

3. The current measurement sensor of claim 1, wherein the coil coupling member is provided with a coupling part coupled to the body case and the body case is provided with a coil coupling part corresponding to the coupling part of the coil coupling member.

4. The current measurement sensor of claim 3, wherein the coupling part of the coil coupling member is configured by a protrusion part and the coil coupling part of the body case is configured by a groove part corresponding to the protrusion part.

5. The current measurement sensor of claim 4, wherein the coil coupling member is insertedly coupled to the body case in one direction and the case coupling part covers the other direction of the coil coupling part.

6. The current measurement sensor of claim 1, wherein the coil coupling member includes a first coil coupling member to which the rogowski coil is coupled and a second coil coupling member coupled to the body case, the second coil coupling member is provided with a coupling part coupled to the body case, and the body case is provided with a coil coupling part corresponding to the coupling part of the coil coupling member.

7. The current measurement sensor of claim 6, wherein the coupling part of the second coil coupling member is configured by a protrusion part and the coil coupling part of the body case is configured by a groove part corresponding to the protrusion part.

8. The current measurement sensor of claim 7, wherein the second coil coupling part is insertedly coupled to the body case in one direction and the case coupling part covers the other direction of the second coil coupling part.

9. The current measurement sensor of claim 6, wherein the second coil coupling member is provided with a coupling part for being coupled to the first coil coupling member and the first coil coupling member is provided with a coupling part corresponding to the coupling part of the second coil coupling member.

10. The current measurement sensor of claim 9, wherein the coupling part of the first coil coupling member is configured by a protrusion part and the coupling part of the second coil coupling member is configured by a groove part.

11. The current measurement sensor of claim 1, wherein the rogowski coil includes:
a coaxial coil;
a coil tube having the coaxial coil inserted thereinto;
a winding coil wound on an outer circumference surface of the coil tube at an equidistant interval; and
a rogowski tube covering the winding coil.

12. The current measurement sensor of claim 1, further comprising a controlling unit connected to the rogowski coil so as to be matched in order to induce a current induced in the rogowski coil as an output voltage.

13. The current measurement sensor of claim 12, further comprising a data cable connected to the controlling unit and outputting the output voltage induced by the controlling unit to an external device.

14. A rogowski coil comprising:
a coaxial coil;
a coil tube having the coaxial coil inserted thereinto;
a winding coil wound on an outer circumference surface of the coil tube at an equidistant interval; and
a rogowski tube covering the winding coil.

15. The rogowski coil of claim 14, wherein the coil tube and the rogowski tube are made of a flexible material.
